(19) United States
(12) Patent Application Publication
(10) Pub. No.: US 2021/0051803 A1
(43) Pub. Date: Feb. 18, 2021

(54) Method for producing a sandwhich arrangement

(71) Applicant: HERAEUS DEUTSCHLAND GMBH & CO. KG, Hanau (DE)

(72) Inventors: Michael SCHÄFER, Kunzell (DE); Nadja PELSHAW, Rodenbach (DE); Yvonne LÖWER, Erlensee (DE); Anton-Zoran MiIRIC, Alzenau (DE)

(73) Assignee: Heraeus Deutschland GmbH & Co. KG, Hanau (DE)

(21) Appl. No.: 16/977,446

(22) PCT Filed: Mar. 5, 2018
(86) PCT No.: PCT/EP2018/055249

§ 371 Date: Sep. 1, 2020

(51) Int. Cl. H05K 3/00; H05K 1/03; H05K 3/34

(52) U.S. Cl. CPC H05K 3/0094; H05K 3/305; H05K 3/3494; H05K 1/0306

(57) ABSTRACT

A method for producing a sandwich arrangement consisting of a first component having a contact surface A, a second component having a contact surface D and a solder located between said contact surfaces A and D,

wherein the solder is produced by melting a solder deposit that is arranged between the two components and connected at the contact surface A or D to one of the components, followed by cooling of the molten solder to below its solidification temperature,
wherein the solder deposit is produced previously by melting a solder preform that is fixed to the relevant contact surface A or D by means of an applied fixing agent from a fixing agent composition, followed by cooling of the molten solder to below its solidification temperature, and
wherein the solder deposit is arranged with its free contact surface facing the corresponding contact surface D or A of the as of yet unconnected component, wherein the fixing agent composition consists of
0 to 97 wt. % (weight %) of at least one solvent selected from the group consisting of water and organic solvents boiling at ≤285° C.,
3 to 100 wt. % of at least one M1 material selected from the group consisting of (i) thermoplastic organic polymers that are meltable between 30 and 180° C. and (ii) non-polymeric organic compounds with no acidic groups that are meltable between 30 and 180° C.,
0 to 20 wt. % of at least one M2 material selected from the group consisting of (iii) organic polymers that are not meltable between 30 and 180° C. and (iv) non-polymeric organic compounds with no acidic groups that are not meltable between 30 and 180° C. and not having a boiling point or having a boiling point above 285° C., and
0 to 30 wt. % of one or more inorganic solid fillers, and
wherein the sum of the surface sections that are provided with the fixing agent, of the contact surfaces A and B or C and D that upon placing the solder preform together form a common overlapping area, in the presence of one or more components (i) in the at least one M1 material is 1500 μm² to 50 area % of the common overlapping area, while, when only one or more of the components (ii) are present in the at least one M1 material said sum is 1500 μm² to 100 area % of the common overlapping area.

The invention relates to a method for producing a sandwich arrangement consisting of a first component that is connected to a second component my means of a solder.

Soldering as a process for substance-to-substance bonding when connecting components and is known to the person skilled in the art. In particular, it is a process that is used for connecting components used in electronics to each other in a mechanically, as well as thermally and electrically conductive manner by means of a given contact surface. Possible solder materials include a solder paste that is arranged between the components that are to be connected or a solder preform placed between them that is melted inside a furnace to form a molten solder resulting in the desired connection of the components after exiting the furnace, followed by cooling and solidifying. Alternatively, a solder paste that is applied or a solder preform that is placed on a component can first be transformed into a solder deposit that is connected to the contact surface of the component. The solder deposit that is connected to the contact surface of the component has a free, outwards facing contact surface and can thereby serve as a solder material in facilitating the production of a solder connection with the further component. To this end, it can be melted inside a furnace to obtain a molten solder, thereby forming the desired connection of the components upon exiting the furnace, cooling, and solidifying. It is problematic, however, that, while moving the arrangement consisting of the one or more components and the solder preform, for example, when it is being transported into the furnace, undesired positional changes can occur relative to the solder preform and the components that are to be connected; similarly, this is also a problem when an arrangement consisting of a component provided with a solder deposit and a further component that is to be connected thereto is moved or transported. In the most unfavorable scenario, a component may not only become dislodged relative to the solder preform and the component that is to be connected or relative to a solder deposit, or slanted, but it may even become detached and drop down. Causes can be, for example, vibrations or acceleration and/or deceleration processes during transportation.

U.S. Pat. No. 5,255,839 discloses the application of a flux having an adhesive effect on the solder deposit of a substrate before a component that is soldered to the substrate is placed on it. The solder deposit is generated ahead of time by means of reflow soldering solder spheres that are applied on a flux that covers a contact surface of the substrate.

U.S. Pat. No. 5,177,134 discloses the use of an adhesive with fluxing properties that is suited for temporarily connecting electronic components when soldering electronic components. A 2,2-disubstituted succinic acid is an essential component of the adhesive.

It is the object of the present invention to develop a method for producing a sandwich arrangement consisting of two components with a solder arranged between them, with the intermediary use of a fixing agent that allows for foregoing the use of a flux, and the production of a satisfactory solder connection between the two components. In the context of the present disclosure, “satisfactory solder connection” denotes a soldered connection that is without voids or, in terms of their number and sizes, with only minimal voids at the boundary between component and solder. Voids of this kind can compromise the mechanically, electrically and/or thermally conductive connection. The fixing agent is to be used in comparatively small amounts, if possible.

It was found that the method according to the invention disclosed below can achieve said object. One key to achieving the object is the use of an applicable fixing agent from a fixing agent composition—which is not to be confused with a flux, i.e., it is not a flux because it does not have the effect of a flux (i.e., it lacks dissolving and eliminating action, respectively, relative to the solder metal oxide or solder metal oxide layer before and/or during soldering)—for fixing a solder preform to a component in a known process for converting the same into a solder deposit that is connected to a component, particularly during associated transportation steps. It has become evident that the fixing agent allows for fixing action in the sense of providing temporarily sufficient adhesion of a solder preform to a component, which is to be provided with a solder deposit and which translates in practice into visibly reduced production rejects, as compared to working without fixing agent. Moreover, it was also evident that, working with a fixing agent, it is possible to forego the use of complex mechanical fixation means. It was further found that the use of the fixing agent corresponding to the method according to the invention results in minor to tolerable influences on the mechanical, thermal and/or electrical connection and performance of components with solder deposit applied thereto or finished soldered sandwich arrangements of components produced therefrom.

The method according to the invention disclosed below can be executed without the use of any flux.

The method according to the invention is a method for producing a sandwich arrangement consisting of a first component having a contact surface A, a second component having a contact surface D, and solder arranged between the contact surfaces A and D,

wherein the solder is produced by melting a solder deposit that is arranged between the two components and connected to one of the components at the contact surface A or D, followed by cooling the molten solder to below its solidification temperature, wherein the solder deposit is produced previously by melting a solder preform that is fixed to the relevant contact surface A or D by means of an applied fixing agent from a fixing agent composition, followed by cooling the molten solder to below its solidification temperature, and
wherein the solder deposit is arranged by the free contact surface thereof facing the corresponding contact surface D or A of the as of yet unconnected component, wherein the fixing agent composition consists of
0 to 97 wt. % (weight %) of at least one solvent selected from the group consisting of water and organic solvents boiling at ≤285° C.,
3 to 100 wt. % of at least one M1 material selected from the group consisting of (i) thermoplastic organic polymers that are meltable between 30 and 180° C. and (ii) non-polymeric organic compounds with no acidic groups that are meltable between 30 and 180° C.,
0 to 20 wt. % of at least one M2 material selected from the group consisting of (iii) organic polymers that are not meltable between 30 and 180° C. and (iv) non-polymeric organic compounds with no acidic groups that are not meltable between 30 and 180° C. and do not have a boiling point or that have a boiling point above 285° C., and
0 to 30 wt. % of one or more inorganic solid fillers, and
wherein the sum of the surface sections that are provided with the fixing agent, of the contact surfaces A and B or C and D that upon placing the solder preform together form a common overlapping area, in the presence of one or more components (i) in the at least one M1 material is 1500 μm² to 50 area % of the common overlapping area, while, when only one or more of the components (ii) are present in the at least one M1 material said sum is 1500 μm² to 100 area % of the common overlapping area.

The terms “organic compound” and “organic polymer” as used herein can also comprise materials containing organic and inorganic components; only purely inorganic materials are not comprised by the terms.

The term “polymers” as used herein also comprises oligomers; both are not to be confused with non-polymeric compounds. The limit between oligomers and polymers is defined herein by the average molecular weight, which can be determined via GPC (gel permeation chromatography, polystyrene standards, polystyrene gel as stationary phase, tetrahydrofuran as mobile phase). Polymers have an average molecular weight Mw over 1000, for example, from 1000 to 300,000, oligomers have a weight average molecular weight Mw of <1000, for example from 500 to <1000.

Contrary to polymers and oligomers, non-polymeric compounds are low-molecular compounds with defined molecular and structural formulae.

The expression “with no acidic group” as used herein denotes with no functionalities functioning as proton donor that can form H₃O⁺ ions in water, such as carboxyl groups, sulfonic acid groups, phenolic OH groups, and the like.

The expression “with no boiling point” that is used herein in connection with compounds of type (iv) refers to representatives thereof with a decomposition point or decomposition range instead of a boiling point.

Accordingly, the method according to the invention provides for fixing a solder preform by means of applying said fixing agent to a contact surface A or D of a component, then for melting the same and for the molten solder that is formed in this manner to be cooled to below its solidification temperature. As a result, a component provided with a solder deposit on its contact surface A or D is obtained. Said component is arranged with the free contact surface of its solder deposit facing the contact surface D or A of a component that is to be connected, wherein fixing agent can be arranged between the contact surfaces that are to be connected. Next, the solder deposit is melted, and the molten solder thus obtained is cooled to below its solidification temperature, whereby the finished soldered sandwich arrangement is formed.

In the context of the invention, preferably, the term “component” is to comprise individual parts. Preferably, said individual parts cannot be further disassembled. These components are particularly components or parts that are used in electronics. The components have contact surfaces, particularly metal contact surfaces.

A distinction is made between a component having a contact surface A and a component having a contact surface D with said latter component being different from the former and, respectively, distinguishable therefrom. To avoid misunderstandings, components with contact surfaces can only be not distinguishable from each other if they are—viewed as free components—identical, or if they are present in a symmetrical arrangement relative to each other. If they are not present in a symmetrical arrangement relative to each other, even identical components can be distinguishable from each other.

The component having a contact surface A and the component having a contact surface D can be of the same type; i.e., in both cases, they can be, for example, substrates, or they are each active or passive components, or they are an active and a passive component. However, it is also possible that the component having a contact surface A is a substrate and the component having a contact surface D is an active or a passive component, or vice versa. The substrates, the active and passive components are, particularly, parts that are used in electronics.

For example, the following embodiments can be distinguished:

| Component having | Component having |
|---|---|
| contact surface A: | contact surface D: |
| Substrate | Substrate |
| Active component | Passive component |
| Passive component | Active component |
| Active component | Active component |
| Passive component | Passive component |
| Substrate | Active component |
| Substrate | Passive component |
| Passive component | Substrate |
| Active component | Substrate |

Examples of substrates are IMS substrates (insulated metal substrates), DCB substrates (direct copper bonded substrates), ceramic substrates, PCBs (printed circuit boards) and lead frames. The sizes of the contact surfaces are, for example, between 0.01 and 200 cm². The contact surfaces can have any shape; for example: round, hexagonal, triangular, preferably rectangular.

Examples of active components are diodes, LEDs (light emitting diodes), dies (semiconductor chips), IGBTs (insulated-gate bipolar transistors), ICs (integrated circuits) and MOSFETs (metal-oxide-semiconductor field-effect transistors). The sizes of the contact surfaces are, for example, from 0.01 to 200 cm². The contact surfaces can have any shape; for example: round, hexagonal, triangular, preferably rectangular.

Examples of passive components are sensors, base boards, heat sinks, connecting elements (e. g., clips), resistors, capacitors, inductors, and antennas. The sizes of the contact surfaces are, for example, between 0.01 and 200 cm². The contact surfaces can have any shape; for example: round, hexagonal, triangular, preferably rectangular.

The solder is a metal solder, for example, tin or alloys rich in tin. Examples of tin-rich alloys are alloys with a tin content of, for example, between 90 to 99.5 wt. % (weight %). Examples of metal alloys are copper, silver, indium, germanium, nickel, lead, bismuth and antimony. The alloys can be leaded or lead-free. Lead-free alloys can be selected, for example, from the group consisting of SnAg, SnBi, SnSb, SnAgCu, SnCu, SnSb, InSnCd, InBiSn, InSn, BiSnAg or SnAgCuBiSbNi. Leaded alloys can be selected, for example, from the group comprising SnPb and SnPbAg. The melting temperatures of the solders can be, for example, between 150 and 500° C., particularly 170 and 350° C.

The solder preforms are solder metals in the form of molded parts, for example, solder foil, solder strip, solder chips or solder cylinders. The solder preforms have discrete contact surfaces B and C; i.e., these contact surfaces B and C are distinct and distinguishable from each other, with the contact surfaces B and C being arranged, for example, on opposite sides of a solder preform. The sizes of the contact surface of types B and C are, for example, between 0.01 and 200 cm², respectively. The contact surfaces of types B and C can have any shape; for example: round, hexagonal, triangular, preferably rectangular.

The thickness of the solder preform can be, for example, from 10 to 750 μm.

According to a first embodiment, the method according to the invention comprises the following sequential steps:

(1) providing a first component having a contact surface A, a second component having a contact surface D, a fixing agent composition, composed as mentioned above (i.e., suitable for applying the fixing agent), as well as a solder preform with discrete contact surfaces B or C, not provided with fixing agent,
(2) applying the fixing agent from the fixing agent composition to the contact surfaces A and/or B,
(3) placing the solder preform by its contact surface B onto the contact surface A with the fixing agent between contact surfaces A and B,
(4) melting the fixed solder preform, thereby forming molten solder,
(5) cooling the molten solder to below its solidification temperature, thereby forming a solder deposit having a free contact surface X,
(6) optionally applying the fixing agent from the fixing agent composition to the contact surfaces D and/or X,
(7) producing a sandwich arrangement from the two components with the solder deposit located between them by arranging the contact surfaces X and D facing each other, with the fixing agent optionally located between them,
(8) melting the solder deposit preform thereby forming molten solder, and
(9) cooling the molten solder to below its solidification temperature, thereby forming a sandwich arrangement from the two components that are connected via their contact surfaces A and D and the solidified solder located between them.

The expression “provided with fixing agent” or “not provided with fixing agent,” is used herein. It indicates whether one or more of the relevant contact surfaces are provided with fixing agent, or whether they are free of the fixing agent. In other words: whether or not fixing agent was applied to one or more of the relevant contact surfaces.

According to a second embodiment, the method according to the invention comprises the following sequential steps:

(1) providing a first component having a contact surface A, a second component having a contact surface D, a fixing agent composition, composed as mentioned above (i.e., suitable for applying the fixing agent), as well as a solder preform with discrete contact surfaces B and C not provided with fixing agent,
(2) applying the fixing agent from the fixing agent composition onto the contact surfaces C and/or D,
(3) placing the solder preform by its contact surface C onto the contact surface D with the fixing agent between contact surfaces C and D,
(4) melting the fixed solder preform, thereby forming molten solder,
(5) cooling the molten solder to below its solidification temperature, thereby forming a solder deposit having a free contact surface Y,
(6) optionally applying the fixing agent from the fixing agent composition to the contact surfaces A and/or Y,
(7) producing a sandwich arrangement from the two components with the solder deposit located between them by arranging the contact surfaces Y and A facing each other, with the fixing agent optionally located between them,
(8) melting the solder deposit thereby forming molten solder, and
(9) cooling the molten solder to below its solidification temperature, thereby forming a sandwich arrangement from the two components that are connected via their contact surfaces A and D and the solidified solder located between them.

According to a third embodiment, the method according to the invention comprises the following sequential steps:

(1) providing a first component having a contact surface A, a second component having a contact surface D, a solder preform having discrete contact surfaces B and C, wherein only contact surface B is provided with the fixing agent, as well as, optionally, a fixing agent composition as mentioned above (i.e. suitable for applying the fixing agent),
(2) optionally applying the fixing agent from the fixing agent composition to the contact surface A,
(3) placing the solder preform by its contact surface B onto the contact surface A with the fixing agent between contact surfaces A and B,
(4) melting the fixed solder preform, thereby forming molten solder,
(5) cooling the molten solder to below its solidification temperature, thereby forming a solder deposit having a free contact surface X,
(6) optionally applying the fixing agent from the fixing agent composition to the contact surfaces D and/or X,
(7) producing a sandwich arrangement from the two components with the solder deposit located between them by arranging the contact surfaces X and D facing each other, with the fixing agent optionally located between them,
(8) melting the solder deposit thereby forming molten solder, and
(9) cooling the molten solder to below its solidification temperature, thereby forming a sandwich arrangement from the two components that are connected via their contact surfaces A and D and the solidified solder located between them.

According to a fourth embodiment, the method according to the invention comprises the following sequential steps:

(1) providing a first component having a contact surface A, a second component having a contact surface D, a solder preform having discrete contact surfaces B and C, wherein only contact surface C is provided with the fixing agent, as well as, optionally, a fixing agent composition as mentioned above (i.e. suitable for applying the fixing agent),
(2) optionally applying the fixing agent from the fixing agent composition to the contact surface D,
(3) placing the solder preform by its contact surface C onto the contact surface D with the fixing agent between contact surfaces C and D,
(4) melting the fixed solder preform, thereby forming molten solder,
(5) cooling the molten solder to below its solidification temperature, thereby forming a solder deposit having a free contact surface Y,
(6) optionally applying the fixing agent from the fixing agent composition to the contact surfaces A and/or Y,
(7) producing a sandwich arrangement from the two components with the solder deposit located between them by arranging the contact surfaces Y and A facing each other, with the fixing agent optionally located between them,
(8) melting the solder deposit, thereby forming molten solder, and
(9) cooling the molten solder to below its solidification temperature, thereby forming a sandwich arrangement from the two components that are connected via their contact surfaces A and D and the solidified solder located between them.

The aforementioned four embodiments of the method according to the invention represent defined sequences of steps that comprise or consist of the respective sequential steps (1) to (9). These nine steps can be sequential steps, one directly following another; i.e., with no intermediate steps, or at least with no substantial intermediate steps, that is to say, with no intermediate steps that change the essence of the method according to the invention. However, partial steps of the providing step (1) can constitute an exception in that, insofar as the further sequence of steps allows or even requires it, said partial steps can be performed or completed at a suitable point during the process and thereby conclude the providing step (1).

Aside from the sandwich arrangements that can be produced by means of the method according to the invention, the present disclosure also comprises arrangements that are obtained or can occur as intermediate products of the method according to the invention.

Such an arrangement that can be obtained as an intermediate product of the first and third embodiments of the method according to the invention comprises an arrangement consisting of a component having a contact surface A and a solder deposit that is connected to said contact surface A by a free contact surface X, which is provided with the fixing agent.

A further such arrangement that can be obtained as an intermediate product of the first and third embodiments of the method according to the invention comprises an arrangement consisting of a first component having a contact surface A and of a second component having a contact surface D, and a solder deposit arranged between said contact surfaces A and D and connected to contact surface A, which is connected, facing contact surface D by its free surface X, by means of the fixing agent. In other words, this is an unsoldered sandwich arrangement consisting of a component with a solder deposit connected to contact surface A thereof, said solder deposit having a free contact surface X, which in turn is connected to the contact surface D of the other component by means of the fixing agent.

A further such arrangement that can be obtained as an intermediate product of the second and fourth embodiments of the method according to the invention comprises an arrangement consisting of a component having a contact surface D and a solder deposit that is connected to said contact surface D, said solder deposit having a free contact surface Y, which is provided with the fixing agent.

A further such arrangement that can be obtained as an intermediate product of the second and fourth embodiments of the method according to the invention comprises an arrangement consisting of a first component having a contact surface A and a second component having a contact surface D and a solder deposit arranged between said contact surfaces A and D and connected to said contact surface D, said solder deposit being connected, facing the contact surface A, by its free surface Y by means of the fixing agent. In other words, this is an unsoldered sandwich arrangement consisting of a component with a solder deposit that is connected to contact surface D thereof, said solder deposit having a free contact surface Y, which in turn is connected to the contact surface A of the other component by means of the fixing agent.

A further such arrangement that can be obtained as an intermediate product of the first and third embodiments of the method according to the invention comprises an arrangement consisting of a component having a contact surface A and a solder preform having discrete contact surfaces B and C with the fixing agent between the contact surfaces A and B.

A further such arrangement that can be obtained as an intermediate product of the second and fourth embodiments of the method according to the invention comprises an arrangement consisting of a component having contact surface D and a solder preform having discrete contact surfaces B and C with the fixing agent between the contact surfaces C and D.

A further such arrangement that can be obtained as an intermediate product of the first to fourth embodiments of the method according to the invention comprises a free component having a contact surface A provided with the fixing agent or a free component having a contact surface D provided with the fixing agent.

A further such arrangement that can be obtained as an intermediate product of the first to fourth embodiments of the method according to the invention comprises a free solder preform having discrete contact surfaces B and C, wherein the contact surfaces B and/or C are provided with the fixing agent.

In the method according to the invention, the contact surfaces are arranged or brought into contact in a manner in which A is facing B or C is facing D. The contact surfaces A and B or C and D form a common overlapping area with each other. If the contact surfaces A and B or C and D, do not have the same dimensions, or if, when they are arranged facing each other, the contact surfaces A and B or C and D are not congruently arranged facing each other, the common overlapping area corresponds to a partial area of at least one of the contact surfaces A and B or C and D constituting the same. The same applies analogously regarding the arrangement facing each other and the contacting of contact surfaces A and Y or D and X.

Presently addressed is the contacting of contact surfaces with or without the fixing agent between the contact surfaces. In this context, the term “contact” denotes a direct contact in the sense of touching and extending to include contact in the sense of approaching to within a negligible distance of, for example, ≤100 μm. The latter applies particularly when the fixing agent is present between the contact surfaces. To avoid misunderstandings: in the case of a substance-to-substance solder connection between contact surfaces, there is only an indirect connection of the contact surfaces that are connected by solder, or soldered, whereas the contact with the connecting solder is a direct contact. Said contacting contact surfaces with the fixing agent between said contact surfaces means that the fixing agent from a fixing agent composition composed as mentioned above, has been applied at least to one of the two relevant contact surfaces, which comprises, in cases when a fixing agent composition contains solvent, as mentioned below, removing the solvent prior to the actual contacting.

The contact surfaces of the types A, B, C and D have on minimal mean surface roughness Ra (determined according to DIN EN ISO 25178-6:2010-06), for example, between 0.1 and 40 μm.

The contact surfaces of the types A, B, C, D, X and Y are generally planar, or substantially planar.

The expression “fixing agent” or “fixing agent applied from a fixing agent composition as mentioned above” are used herein. This means the fixing agent that is applied to a relevant contact surfaces A, B, C, D, X or Y in the state and under the conditions immediately before or during the arranging and contacting, while facing each other, the contact surfaces of the solder preform and component with the fixing agent therebetween, or immediately before or during fixing the solder deposit with the fixing agent between the contact surfaces A and Y or D and X. Said conditions comprise, for example, the conditions relating to temperature, air pressure and humidity, or the temperature and type of the environmental atmosphere prevailing during the arranging and contacting. Accordingly, optionally, it can be expedient to execute an arranging and contacting at an elevated temperature in any case, however below the melting temperature of the solder. This can be done, for example, using heated contact surfaces.

The fixing agent is applied from a fixing agent composition that is composed as mentioned above.

The term “to apply” that is used herein in connection with the application of a fixing agent from a fixing agent composition that is composed as mentioned above, onto a contact surface can include a thermal and/or photochemical treatment optionally taking place at the same time and/or following the actual applying. In the case of a solvent containing fixing agent, the term “to apply” includes in each case removal of solvent after the actual applying, particularly an almost complete or, preferably, complete removal of solvent, for example, by drying, which can be supported or effected by means of the usual measures, such as, for example, heating and/or reducing pressure. Almost complete to complete removal of solvent means a removal of >50 to 100 wt. %, preferably >80 to 100 wt. % of the solvent originally contained in the solvent-containing fixing agent composition.

As mentioned above, the fixing agent composition consists of

0 to 97 wt. % (weight %) of at least one solvent selected from the group consisting of water and organic solvents boiling at ≤285° C.,
3 to 100 wt. % of at least one M1 material selected from the group consisting of (i) thermoplastic organic polymers that are meltable between 30 and 180° C. and (ii) non-polymeric organic compounds with no acidic groups that are meltable between 30 and 180° C.,
0 to 20 wt. % of at least one M2 material selected from the group consisting of (iii) organic polymers that are not meltable between 30 and 180° C. and (iv) non-polymeric organic compounds with no acidic groups that are not meltable between 30 and 180° C. and do not have a boiling point or that have a boiling point above 285° C., and 0 to 30 wt. % of one or more inorganic solid fillers.

Corresponding to its content of 0 to 97 wt. % of at least one solvent selected from the group consisting of water and organic solvents boiling at ≤285° C., the fixing agent composition can be a composition that is free of solvent, an aqueous composition that is free of organic solvents, an aqueous composition containing organic solvents or a non-aqueous composition containing organic solvent.

Examples of solvent-free fixing agent compositions are fixing agent compositions that are solid to tacky when they are being applied, for example, in the form of a film, strip, powder, drops, hotmelt material, oily or resin-like materials. Depending on the consistency of a respective solvent-free fixing agent composition, the person skilled in the art will select a suitable method for applying the substance to a contact surface A, B, C, D, X or Y.

Examples of aqueous fixing agent compositions are aqueous fixing agent compositions that are free of organic solvents and those that contain organic solvents. These compositions can be solutions, suspensions or dispersions with rheological properties that can fall within a wide range from liquid to paste-like. Accordingly, the aqueous fixing agent compositions can be applied in different ways to a contact surface A, B, C, D, X or Y; for example, by jetting, dispensing, spraying, brushing, dabbing, immersing or printing, followed by drying for an almost complete to preferably complete removal of the water and the organic solvent optionally contained therein.

The non-aqueous fixing agents that contain an organic solvent can be solutions, suspensions or dispersions with rheological properties that can fall within a wide range from liquid to paste-like. Correspondingly, the non-aqueous fixing agent compositions that contain organic solvent can be applied in different ways to a contact surface A, B, C, D, X or Y; for example, via jetting, dispensing, spraying, brushing, dabbing, immersing or printing, followed by drying for an almost complete to preferably complete removal of the organic solvent.

Preferably, the at least one M1 material includes thermoplastic organic polymers of type (i) that are meltable between 30 and 180° C., of those, particularly partially or fully synthetic representatives. Preferably, the at least one M1 material does not comprise any non-synthetic organic polymers, i.e., no organic polymers of natural origin, such as natural resins. Examples of natural resins are tree resins, such as colophonium resin. There are no material restrictions for the thermoplastic organic polymers that are meltable between 30 and 180° C. They can be, for example, vinyl copolymers, (meth)acryl copolymers, polyesters, polyurethanes, polymer precursors of such aforementioned polymers, and/or cellulose derivatives, such as, for example, cellulose ethers and cellulose esters. (Meth)acryl copolymers and cellulose derivatives, such as methyl cellulose or ethyl cellulose are particularly preferred. The thermoplastic organic polymers that are meltable between 30 and 180° C. can have acidic groups, corresponding to an acid number in the range from 0 to 50 mg KOH/g, preferably with an acid number below 25 mg KOH/g; particularly preferably they have no acidic groups and no acid number. The person skilled in the art is familiar with ways of determining the acid number, such as, for example, the number of carboxyl groups of organic polymers; for example, the determination according to DIN EN ISO 2114.

Preferred examples of non-polymeric organic compounds of type (ii) with no acidic groups that are meltable between 30 and 180° C., are lactams, such as, for example, laurin lactam; and fatty alcohols, such as, for example, 1-dodecanol (lauryl alcohol), 1-tetradecanol (myristyl alcohol), 1-hexadecanol (cetyl alcohol), 1-heptadecanol (margaryl alcohol), 1-octadecanol (stearyl alcohol), 1-eicosanol (arachidyl alcohol), 1-docosanol (behenyl alcohol), 1-tetracosanol (lignoceryl alcohol), 1-hexacosanol (ceryl alcohol), 1-octacosanol (montanyl alcohol), 1-triacontanol (melissyl alcohol).

Further examples of non-polymeric organic compounds of type (ii) with no acidic groups that are meltable between 30 and 180° C. are respective individual components of blends of organic substances that are meltable between 30 and 180° C., such as oils, fats, waxes such as, for example, natural waxes, such as, for example, beeswax, paraffin waxes and vaseline.

The fixing agent composition contains 0 to 20 wt. % of at least one M2 material selected from the group consisting of (iii) organic polymers that are not meltable between 30 and 180° C., and (iv) non-polymeric organic compounds with no acidic groups that are not meltable between 30 and 180° C. and not having a boiling point or having a boiling point above 285° C. The organic polymers of type (iii) differ from those of type (i) and, preferably, they also have no acidic groups. For example, they can be non-thermoplastic organic polymers or organic polymers that are meltable outside of the range of 30 to 180° C. The non-polymeric organic compounds of type (iv) differ from those of type (ii); for example, they can be non-polymeric organic compounds with no acidic groups that are meltable outside of the range of 30 to 180° C.; alternatively, they can be non-polymeric organic compounds with no acidic groups that boil without decomposition above 285° C. and can be distilled, or that have a decomposition point or decomposition range instead of a boiling point. The latter cannot be distilled under normal conditions.

Representatives of the M2 material are, for example, additives, such as, for example, wetting and rheological additives.

The fixing agent composition contains 0 to 30 wt. % of one or more inorganic solid fillers. Examples of inorganic solid fillers are silicon dioxide and aluminum oxide.

The sum of the surface sections provided with fixing agent of the contact surfaces A and B or C and D which together form a common overlapping area, is, when one or more components of type (I) are present in the at least one M1 material, 1500 μm² to 50 area % of the common overlapping area, preferably 1500 μm² to 20 area %, particularly 1500 μm² to 10 area %. When solely one or more components of type (ii) are present in the at least one M1 material, said sum is 1500 μm² to 100 area % of the common overlapping area, preferably 1500 μm² to 50 area %, particularly 1500 μm² to 20 area % or even only 1500 μm² to 10 area %.

The same applies for the possible fixing of the free contact surface X or Y of the solder deposit; here, the sum of the surface sections provided with the applied fixing agent from the fixing agent composition, of the contact surfaces A and Y or D and X forming together a common overlapping area in the presence of one or more components of type (i) in the at least one M1 material, can be 1500 μm² to 50 area % of the common overlapping area, preferably 1500 μm² to 20 area %, particularly 1500 μm² to 10 area %. When solely one or more components of type (ii) are present in the at least one M1 material, said sum is 1500 μm² to 100 area % of the common overlapping area, preferably 1500 μm² to 50 area %, particularly 1500 μm² to 20 area % or even only 1500 μm² to 10 area %.

In all of the aforementioned cases, the fixing agent can be present as an individual continuous area or distributed over several areas that are separated from each other; for example, as one or more area elements, for example, as dots, lines, line or dot patterns. Individual area elements or all area elements can also extend beyond a respective overlapping area boundary line; for example, in such a manner that the fixing agent composition is intentionally or unintentionally applied extending beyond a respective overlapping area boundary line. For example, an area element can partially cover the overlapping area boundary line and in doing so, it can be located partially inside and partially outside the overlapping area. A partial or complete frame-like covering of the overlapping area boundary line is also possible. Individual continuous area elements that do not touch the overlapping area boundary line can have an area of, for example, 1500 μm² to 10 area % of the respective common overlapping area, preferably 1500 μm² to 5 area %, particularly 1500 μm² to 2 area %. The one or more area elements can extend sufficiently far beyond the corresponding plane of the contact surface to enable a fixed connection of contact surfaces that are to be connected. This way, the one or more area elements consisting of the fixing agent can have a thickness, for example, in the range from 1 to 100 μm, or preferably 1 to 50 μm, or more preferably 1 and 20 μm, or most preferred 1 and 10 μm; this applies particularly regarding non-molten or incompletely molten fixing agents.

The applied fixing agent can differ qualitatively and/or quantitatively in terms of the composition thereof relative to the fixing agent composition. For example, this can be the result of its application and/or removal of solvent or of drying and/or a thermal and/or photochemical treatment performed intentionally as part of the application. In case of an applied fixing agent from a fixing agent composition that contains solvent, the solvent content thereof relative to the fixing agent composition is reduced by >50 to 100 wt. %, preferably by >80 to 100 wt. %. In other words, compared to the solvent-containing fixing agent composition, in the applied fixing agent more than half, preferably more than 80 wt. % of the solvent originally contained in the solvent-containing fixing agent composition, has been removed.

A fixing agent that differs in its composition from the fixing agent composition mentioned above can consist of, for example,

0 to 10 wt. % of at least one solvent selected from the group consisting of water and organic solvents boiling at ≤285° C.,
65 to 100 wt. % of at least one M1 material selected from the group consisting of (i) thermoplastic organic polymers that are meltable between 30 and 180° C. and (ii) non-polymeric organic compounds with no acidic groups that are meltable between 30 and 180° C.,
0 to 25 wt. % of at least one M2 material selected from the group consisting of (iii) organic polymers that are not meltable between 30 and 180° C. and (iv) non-polymeric organic compounds with no acidic groups that are not meltable between 30 and 180° C. and do not have a boiling point or have a boiling point above 285° C., and
0 to 35 wt. % of one or more inorganic solid fillers.

The fixing agent demonstrates an adhesion-promoting behavior between the contact surfaces A and B, C and D, A and Y or D and X that are to be connected; i.e., at least under the conditions prevailing when arranging the respective contact surfaces and contacting them with the fixing agent arranged between them, it is tacky and/or causes adhesion of the respective contact surfaces.

The four embodiments of the method according to the invention mentioned above each comprise a placing of the solder preform, for example, placing the solder preform on a component, or vice versa. Said placing occurs in the sense of arranging the contact surfaces A and B or C and D in a manner facing each other.

Placing the solder preform and producing the solder deposit, as well as producing the as yet unsoldered sandwich arrangement downstream can occur, for example, within a temperature range from room temperature to below the melting temperature of the solder, for example, up to 10° C. below the melting temperature of the solder.

After placing the solder preform, the solder deposit is produced. This comprises melting the solder preform, thereby forming molten solder, and subsequent cooling of the molten solder to below its solidification temperature.

For the purpose of melting the preform, the arrangement consisting of the component and solder preform with the fixing agent between the contract surfaces A and B or C and D is conveyed into a furnace with a furnace temperature that is above the melting temperature of the solder. The dwell time inside the furnace and the furnace temperature are designed to allow for the complete melting of the solder preform. For example, the dwell time inside the furnace is between 1 to 60 minutes at a furnace temperature of, for example, between 150 and 500° C., particularly 170 and 350° C. The melting process can be carried out as a batch process or as a continuous process.

It is not completely understood what happens with the fixing agent during the melting process.

After exiting the furnace, the arrangement consisting of the component and the molten solder cools down, and the solder solidifies after cooling to below its solidification temperature, thereby forming the component provided with the solder deposit. In case of a component with a contact surface A, the solder deposit has a free contact surface X; in case of a component with a contact surface D, the solder deposit has a free contact surface Y.

The four embodiments of the method according to the invention mentioned above have in common the production of an as yet unsoldered sandwich arrangement consisting of the two components with the solder deposit located between them, optionally with the fixing agent between the contact surfaces A and Y or D and X, followed by the actual soldering, thereby forming the finished soldered sandwich arrangement.

By arranging the contact surfaces Y or X facing the contact surfaces A or D optionally with the fixing agent located between them, the unsoldered sandwich arrangement consisting of a component provided with the solder deposit and a further component to be connected therewith via the free contact surface of the solder deposit is created.

The actual solder connection process occurs after forming the as yet unsoldered sandwich arrangement. Said solder connection process comprises the melting of the solder deposit, thereby forming the molten solder and subsequent cooling of the molten solder to below its solidification temperature, thereby forming a finished sandwich arrangement consisting of the two components that are connected via their contact surfaces A and D and the solidified solder located between them.

For the purpose of melting the solder deposit, the sandwich arrangement consisting of the two components with the solder deposit located between them, optionally with the fixing agent between the contact surfaces A and Y or D and X, is conveyed into a furnace with a furnace temperature that is above the melting temperature of the solder. The dwell time inside the furnace and the furnace temperature are designed to allow for the complete melting of the solder deposit. For example, the dwell time inside the furnace is between 1 to 60 minutes at a furnace temperature of, for example, in the range from 150 to 500° C., particularly 170 to 350° C. The melting process can be carried out as a batch process or as a continuous process.

It is not completely understood what happens with the fixing agent that is optionally present during the melting process and/or solder process.

After exiting the furnace, the sandwich arrangement consisting of the two components and the molten solder cools down and the solder solidifies after cooling below its solidification temperature, thereby forming the product of the method according to the invention which is the finished sandwich arrangement consisting of the first component having contact surface A, the second component having the contact surface D and with the solder located between the contact surfaces A and D, thereby connecting the two components mechanically, electrically and thermally conductively.

### EXAMPLES

### Example 1 (According to the Invention)

A fixing agent composition consisting of 20 wt. % DEGALAN® LP 63/11 (acryl copolymer available from Evonik Industries AG, acid number 6 mg KOH/g, MW 30,000) dissolved in 80 wt. % α-terpineol was printed using a mask, 20 μm thick with a round opening and a diameter of 40 μm onto a copper side of a DCB substrate (320 μm thickness Al₂O₃ ceramic with bilateral 200 μm copper lamination). The fixing agent composition applied in this manner was then dried for 20 min at 80° C. in a convection drying oven. A fixing center measuring 2000 μm² and 3 μm thick was obtained. A solder preform measuring 10 mm×10 mm×0.1 mm (tin-silver alloy having a 3.5 wt. % silver content) was placed, machine-centered, on said fixing center. This was done with a Datacon 2200 evo placement device, wherein the DCB substrate was preheated to 130° C. prior to the actual placement, and the solder preform was placed on the fixing center applying a force of 1 Newton.

The arrangement created in this manner was exposed, inside a soldering furnace, to a temperature profile of 6 minutes at 180° C. followed by 3 minutes at 260° C. After removing it from the furnace, the arrangement was allowed to cool to room temperature. A solder deposit had formed from the solder preform solidly connected to the copper side of the DCB.

In a further step, the printing and drying of the fixing agent composition was repeated, analogous to the process described above, on the outward facing side of the solder deposit. Subsequently, an IGBT measuring 10 mm×10 mm×0.18 mm was placed onto the fixing center, which had been applied to the solder deposit in this manner, under the same conditions and using the same placement apparatus.

The sandwich arrangement created in this manner and as of yet unsoldered, was exposed, inside a soldering furnace, to a temperature profile of 6 minutes at 180° C. followed by 3 minutes at 260° C. resulting in the complete melting of the solder. After removing it from the furnace, the sandwich arrangement was allowed to cool to room temperature.

After cooling, the thermal conductivity of the soldered connection inside the sandwich arrangement was determined by means of a laser flash analysis (instrument LFA 467 from Netzsch, Germany, energy pulse coming from the IGBT side) to be 36 Wm⁻¹K⁻¹.

### Example 2 (According to the Invention)

Contrary to Example 1, the fixing agent composition was printed by means of a mask, 20 μm thick with four square openings each measuring 9 mm² in a 2·2 arrangement spaced at 2 mm each. Four fixing agent area elements measuring about 10 mm² in size and 3 μm thickness were obtained (in total about 40 area % coverage of the respective overlapping area after placement of the solder preform or after placement with the IGBT).

The thermal conductivity determination resulted in a value of 22 Wm⁻¹K⁻¹.

### Example 3 (Comparison)

Contrary to Example 1, the fixing agent composition was printed by means of a mask, 20 μm thick with four square openings each measuring 13 mm² in a 2·2 arrangement spaced at 2 mm each. Four fixing agent area elements measuring about 13.5 mm² in size and 3 μm thickness were obtained (in total about 55 area % coverage of the respective overlapping area after placement of the solder preform or after placement with the IGBT).

The thermal conductivity determination resulted in a value of 15 Wm⁻¹K⁻¹.

A thermal conductivity of >20 Wm⁻¹K⁻¹ is a satisfactory result.

1. A method for producing a sandwich arrangement from of a first component having a contact surface A, a second component having a contact surface D, and solder located between the contact surfaces A and D,
wherein the solder is produced by melting a solder deposit that is arranged between the two components and connected to one of the components at the contact surface A or D, followed by cooling the molten solder to below its solidification temperature,
wherein the solder deposit is produced previously by melting a solder preform that is fixed to the relevant contact surface A or D by means of an applied fixing agent from a fixing agent composition, followed by cooling the molten solder to below its solidification temperature, and
wherein the solder deposit is arranged by the free contact surface thereof facing the corresponding contact surface D or A of the as of yet unconnected component,
wherein the fixing agent composition consists of
0 to 97 wt. % (weight %) of at least one solvent selected from the group consisting of water and organic solvents boiling at ≤285° C.,
3 to 100 wt. % of at least one M1 material selected from the group consisting of (i) thermoplastic organic polymers that are meltable between 30 and 180° C. and (ii) non-polymeric organic compounds with no acidic groups that are meltable between 30 and 180° C.,
0 to 20 wt. % of at least one M2 material selected from the group consisting of (iii) organic polymers that are not meltable between 30 and 180° C. and (iv) non-polymeric organic compounds with no acidic groups that are not meltable between 30 and 180° C. and do not have a boiling point or that have a boiling point above 285° C., and
0 to 30 wt. % of one or more inorganic solid fillers, and
wherein the sum of the surface sections that are provided with the fixing agent, of the contact surfaces A and B or C and D, that upon placing the solder preform together form a common overlapping area, in the presence of one or more components (i) in the at least one M1 material is 1500 μm² to 50 area % of the common overlapping area, while, when only one or more of the components (ii) are present in the at least one M1 material said sum is 1500 μm² to 100 area % of the common overlapping area.

2. The method according to claim 1, comprising the following sequential steps:
(1) providing a first component having a contact surface A, a second component having a contact surface D, the fixing agent composition, as well as a solder preform with discrete contact surfaces B and C not provided with fixing agent,
(2) applying the fixing agent from the fixing agent composition to the contact surfaces A and/or B,
(3) placing the solder preform by its contact surface B onto the contact surface A with the fixing agent between contact surfaces A and B,
(4) melting the fixed solder preform, thereby forming molten solder,
(5) cooling the molten solder to below its solidification temperature, thereby forming a solder deposit having a free contact surface X,
(6) optionally applying the fixing agent from the fixing agent composition to the contact surfaces D and/or X,
(7) producing a sandwich arrangement from the two components with the solder deposit located between them by arranging the contact surfaces X and D facing each other, with the fixing agent optionally located between them,
(8) melting the solder deposit, thereby forming molten solder, and
(9) cooling the molten solder to below its solidification temperature, thereby forming a sandwich arrangement from the two components that are connected via their contact surfaces A and D and the solidified solder located between them.

3. The method according to claim 1, comprising the following sequential steps:
(1) providing a first component having a contact surface A, a second component having a contact surface D, the fixing agent composition, as well as a solder preform with discrete contact surfaces B and C not provided with fixing agent,
(2) applying the fixing agent from the fixing agent composition to the contact surfaces C and/or D,
(3) placing the solder preform by its contact surface C onto the contact surface D with the fixing agent between contact surfaces A and B,
(4) melting the fixed solder preform, thereby forming molten solder,
(5) cooling the molten solder to below its solidification temperature, thereby forming a solder deposit having a free contact surface Y,
(6) optionally applying the fixing agent from the fixing agent composition to the contact surfaces A and/or Y,
(7) producing a sandwich arrangement from the two components with the solder deposit located between them by arranging the contact surfaces Y and A facing each other, with the fixing agent optionally located between them,
(8) melting the solder deposit, thereby forming molten solder, and
(9) cooling the molten solder to below its solidification temperature, thereby forming a sandwich arrangement from the two components that are connected via their contact surfaces A and D and the solidified solder located between them.

4. The method according to claim 1, comprising the following sequential steps:
(1) providing a first component having a contact surface A, a second component having a contact surface D, a solder preform having discrete contact surfaces B and C, wherein only contact surface B is provided with the fixing agent, as well as, optionally, the fixing agent composition,
(2) optionally applying the fixing agent from the fixing agent composition to the contact surface A,
(3) placing the solder preform by its contact surface B onto the contact surface A with the fixing agent between contact surfaces A and B,
(4) melting the fixed solder preform, thereby forming molten solder,
(5) cooling the molten solder to below its solidification temperature, thereby forming a solder deposit having a free contact surface X,
(6) optionally applying the fixing agent from the fixing agent composition to the contact surfaces D and/or X,
(7) producing a sandwich arrangement from the two components with the solder deposit located between them by arranging the contact surfaces X and D facing each other, with the fixing agent optionally located between them,
(8) melting the solder deposit, thereby forming molten solder, and
(9) cooling the molten solder to below its solidification temperature, thereby forming a sandwich arrangement from the two components that are connected via their contact surfaces A and D and the solidified solder located between them.

5. The method according to claim 1, comprising the following sequential steps:
(1) providing a first component having a contact surface A, a second component having a contact surface D, a solder preform having discrete contact surfaces B and C, wherein only contact surface C is provided with the fixing agent, as well as, optionally, the fixing agent composition,
(2) optionally applying the fixing agent from the fixing agent composition to the contact surface D,
(3) placing the solder preform by its contact surface C onto the contact surface D with the fixing agent between contact surfaces C and D,
(4) melting the fixed solder preform, thereby forming molten solder,
(5) cooling the molten solder to below its solidification temperature, thereby forming a solder deposit having a free contact surface Y,
(6) optionally applying the fixing agent from the fixing agent composition to the contact surfaces A and/or Y,
(7) producing a sandwich arrangement from the two components with the solder deposit located between them by arranging the contact surfaces Y and A facing each other, with the fixing agent optionally located between them,
(8) melting the solder deposit, thereby forming molten solder, and
(9) cooling the molten solder to below its solidification temperature, thereby forming a sandwich arrangement from the two components that are connected via their contact surfaces A and D and the solidified solder located between them.

6. An intermediate product of the method according to claim 2 in the form of an arrangement consisting of a first component having a contact surface A and a second component having a contact surface D and a solder deposit that is arranged between said contact surfaces A and D and connected to contact surface A, which is connected, facing the contact surface D, by its free surface X, by means of the applied fixing agent from the fixing agent composition, or according to claim 3 or 5 in the form of an arrangement consisting of a first component having a contact surface A and a second component having a contact surface D and a solder deposit that is arranged between said contact surfaces A and D and connected to contact surface D, which is connected, facing the contact surface A, by its free surface Y, by means of the applied fixing agent from the fixing agent composition.

7. An intermediate product of the method according to claim 4 in the form of an arrangement consisting of a first component having a contact surface A and a second component having a contact surface D and a solder deposit that is arranged between said contact surfaces A and D and connected to contact surface A, which is connected, facing the contact surface D, by its free surface X, by means of the applied fixing agent from the fixing agent composition, or according to claim 3 or 5 in the form of an arrangement consisting of a first component having a contact surface A and a second component having a contact surface D and a solder deposit that is arranged between said contact surfaces A and D and connected to contact surface D, which is connected, facing the contact surface A, by its free surface Y, by means of the applied fixing agent from the fixing agent composition.
